(19) United States
(12) Patent Application Publication
(10) Pub. No.: US 2003/0095438 A1
(43) Pub. Date: May 22, 2003

(54) Nonvolatile semiconductor memory device having function of determining good sector

(75) Inventor: Akira Hosogane, Hyogo (JP)

Correspondence Address: McDERMOTT, WILL & EMERY, 600 13th Street, N.W., Washington, DC, 20005-3096, US

(73) Assignee: Mitsubishi Denki Kabushiki Kaisha

(21) Appl. No.: 10/133,679

(22) Filed: Apr. 29, 2002

(30) Foreign Application Priority Data
Aug. 8, 2001 (JP) 2001-240728(P)

(51) Int. Cl. G11C 11/34

(52) U.S. Cl. 365/185.21

(57) ABSTRACT

Transistors are provided on both sides of sense latches. When a good sector code “10101100” is latched by sense latches, a current sense amplifier detects that common drain lines are non-conductive, thereby determining whether a good sector code is written in each sector or not. As a result, this flash memory can determine whether each of sectors is good or not without outputting a good sector code from the flash memory in which a good sector code is written in a good sector.

### BACKGROUND OF THE INVENTION

1. Field of the Invention

The present invention relates to a nonvolatile semiconductor memory device and, more particularly, a flash memory capable of determining a good sector.

2. Description of Background Art

FIG. 13 is a block diagram showing a general configuration of a data storage type flash memory as one of nonvolatile semiconductor memory devices. In the flash memory of the data storage type, reading operation is performed in two stages. At the first stage, in response to a sector address SA supplied from the outside via a sector address buffer 12, a sector decoder 13 selectively drives word lines in a memory array 11 so that data of a predetermined unit called a sector is transferred in a lump from memory array 11 to a data register 14. At the second stage, in response to a serial clock signal SC for reading supplied from the outside, a column address counter 15 generates a column address signal CA (concretely, 000h to 83Fh). In response to column address CA, a column selecting circuit 16 selects data in data register 14 word by word, and outputs the selected data to the outside via a main sense amplifier 18.

An operation of reading data in a binary flash memory will now be described. FIG. 14 is a circuit diagram showing main components of the binary flash memory. FIG. 15 is a diagram showing a threshold distribution of binary memory cells in FIG. 14. A pair of bit lines B and /B are precharged and a word line W is set to a read voltage RV. When the threshold of a memory cell MC is higher than read voltage RV (status ST1 in FIG. 1), memory cell MC is not turned on. Consequently, the voltage on bit line B does not change. On the other hand, when the threshold of memory cell MC is lower than read voltage RV (status ST0 in FIG. 15), memory cell MC is turned on. Consequently, the voltage on bit line B becomes 0V. A sense latch SL senses a potential difference between bit lines B andBand latches data “1” or “0”. A column selection gate YG outputs the data of sense latch SL synchronously with a serial clock signal.

An operation of reading data in a four-value flash memory will now be described. FIG. 16 is a circuit diagram showing main components of the four-value flash memory. FIG. 17 is a diagram showing a threshold distribution of a four-value memory cell in FIG. 16. In a manner similar to the binary flash memory, sense latch SL is provided in the center. Different from the binary flash memory, data latches DLL and DLR for latching and saving data read from memory cell MC by sense latch SL are provided on both sides. To read data from memory cells MC, word line W is sequentially set to read voltages RV1, RV2, and RV3. In the case of read voltage RV1, memory cell MC having a threshold lower than read voltage RV1 is turned on (status ST0 in FIG. 17). In the case of read voltage RV2, memory cell MC having a threshold lower than read voltage RV2 is turned on (statuses ST0 and ST1 in FIG. 17). In the case of read voltage RV3, memory cell MC having a threshold lower than read voltage RV3 is turned on (statuses ST0 to ST2 in FIG. 17). Data in memory cell MC read by sense latch SL is transferred to data latches DLL and DLR. Column selection gates YGL and YGR output 2-bit data synchronously with the serial clock signal.

Even when such a flash memory partly includes bad sectors, it is shipped as a conforming item under condition that good sectors are presented to the user. Concretely, in a predetermined column address in a good sector, a good sector code indicating that the sector is good is written, so that the user can recognize a good sector which can be used. A controller reads data from the predetermined column address in each sector in response to a normal read command. When the good sector code is written, the sector can be used.

FIG. 18 is an address map showing one sector in which the good sector code is written. The sector has a storage area of 2112 (=2K+64) bytes in which column addresses 000h to 83Fh are assigned. In column addresses 820h to 825h, a 6-byte good sector code “1Ch, 71h, C7h, 1Ch, 71h, and C7h” is written.

FIG. 19 is a flowchart showing an operation of retrieving a good sector by a controller. First, a read command is received (S1). Subsequently, the address of a sector which will be determined to be good or not is received (S2) and a predetermined column address (820h to 825h) is received (S3). The controller waits until data in the predetermined column address is latched by data register 14 (S4). After that, serial clock signal SC for reading is received (S5). Since the data in data register 14 is read in response to serial clock signal SC, the read data is obtained (S6). By repeating the steps S5 and S6 by an amount of six bytes (S7), data of six bytes is obtained byte by byte. Whether the obtained data coincides with the good sector code or not is determined (S8). If YES, the sector is determined as a good sector (S9). If NO, the sector is determined as a bad sector (S10).

In the case of the conventional flash memory, to determine whether each of sectors is good or not, 6-byte data has to be output to the outside byte by byte and compared with a good sector code. There is consequently a problem that it takes time.

### SUMMARY OF THE INVNETION

An object of the present invention is to provide a nonvolatile semiconductor memory device capable of determining whether a nonvolatile memory cell is good or not at high speed.

According to an aspect of the invention, a nonvolatile semiconductor memory device includes a plurality of nonvolatile memory cells, a plurality of bit line pairs, a plurality of latch circuits, and a determining circuit. The plurality of pairs of bit lines are connected to the plurality of nonvolatile memory cells. The plurality of latch circuits provided in correspondence with the plurality of pairs of bit lines. Each latch circuit latches data on a corresponding bit line pair. The determining circuit determines whether two or more latch circuits out of the plurality of latch circuits latch predetermined data or not.

In the nonvolatile semiconductor memory device, a good sector code is preliminarily written in a good nonvolatile memory cell. Data read from the nonvolatile memory cell to a bit line pair is latched by the latch circuit. Whether the latched data is a good sector code or not is determined by the determining circuit. That is, whether the latched data is the good sector code or not is determined without being output to the outside. Consequently, whether the nonvolatile memory cell is good or not can be determined at high speed.

Preferably, each of the latch circuits has an input node connected to one of bit lines in a corresponding bit line pair. The determining circuit includes a plurality of transistors, a common line, and a detecting circuit. The plurality of transistors are provided in correspondence with the two or more latch circuits. Each transistor has a control electrode connected to an input node of a corresponding latch circuit. The common line is connected to a one-way conducting electrode of each of the plurality of transistors. The detecting circuit detects that the common line is non-conducting.

In this case, when a good sector code is latched by the latch circuit, all the transistors are turned off and the common line is made non-conducting. When non-conduction of the common line is detected by the detecting circuit, it can be determined that the nonvolatile memory cell is good.

Preferably, each of the latch circuits includes a sense latch having a first input node connected to one of bit lines of a corresponding bit line pair and a second input node connected to the other bit line. The determining circuit includes a plurality of first and second transistors provided in correspondence with two or more sense latches included in the two or more latch circuits. The gate of each of the first transistors is connected to a first input node of a corresponding sense latch. The gate of each of the second transistors is connected to a second input node of a corresponding sense latch. The determining circuit further includes a first common drain line, a second common drain line, and a detecting circuit. The first common drain line is connected to drains of the plurality of first transistors. The second common drain line is connected to drains of the plurality of second transistors. The detecting circuit detects that the first and second common drain lines are non-conducting.

In this case, when the good sector code is latched by the sense latch, all the first and second transistors are turned off, and the first and second common drain lines are made non-conducting. Therefore, when the non-conduction of the first and second common drain lines is detected, the nonvolatile memory cell can be determined as a good cell.

More preferably, the detecting circuit includes a first detector and a second detector. The first detector detects that the first common drain line is non-conducting. The second detector detects that the second common drain line is non-conducting.

Alternately, the first and second common drain lines are connected to each other.

Preferably, the two or more latch circuits and the determining circuit are divided into a plurality of groups. Each of the groups includes a plurality of transistors, a common line, and a detecting circuit. The plurality of transistors are provided in correspondence with a plurality of latch circuits in the group. Each transistor has a control electrode connected to an input node of a corresponding latch circuit. The common line is connected to a one-way conducting electrode of each of the plurality of transistors. The detecting circuit detects that the common line is non-conducting.

In this case, by changing the combination of the plurality of groups, a plurality of good sector codes can be determined.

Preferably, the nonvolatile semiconductor memory device further includes a plurality of verification transistors, a verification common line, and a detecting circuit for verification. The plurality of verification transistors are provided in correspondence with latch circuits other than the two or more latch circuits out of the plurality of latch circuits. Each verification transistor has a control electrode connected to an input node of a corresponding latch circuit. The verification common line is connected to a one-way conducting electrode of each of the plurality of verification transistors. The detecting circuit for verification detects that the verification common line is non-conducting.

In this case, the transistor for determining a good sector code also serves as the verification transistor.

According to another aspect of the invention, a nonvolatile semiconductor memory device has a plurality of nonvolatile memory cells, a plurality of bit line pairs, a plurality of sense latches, a plurality of first data latches, a plurality of second data latches, a plurality of first and second transistors, and a plurality of third and fourth transistors. The plurality of pairs of bit lines are connected to the plurality of nonvolatile memory cells. The plurality of sense latches are provided in correspondence with the plurality of pairs of bit lines. Each of the sense latches has a first input node connected to one of bit lines of a corresponding bit line pair and a second input node connected to the other bit line of the corresponding bit line pair. The plurality of first data latches are provided in correspondence with bit lines each of which is one of bit lines of each of the plurality of bit line pairs. Each of the first data latches has a first input node connected to the corresponding one of bit lines and a second input node. The plurality of second data latches are provided in correspondence with the other bit lines of the plurality of bit line pairs. Each of the second data latches has a first input node and a second input node connected to the corresponding other bit line. The plurality of first and second transistors are provided in correspondence with two or more data latches out of the plurality of first data latches. The plurality of third and fourth transistors are provided in correspondence with two or more data latches out of the plurality of second data latches. The gate of each of the first transistors is connected to a first input node of a corresponding first data latch. The gate of each of the second transistors is connected to a second input node of a corresponding first data latch. The gate of each of the third transistors is connected to a first input node of a corresponding second data latch. The gate of each of the fourth transistors is connected to a second input node of a corresponding second data latch. The nonvolatile semiconductor memory device further includes a first common drain line, a second common drain line, and a detecting circuit. The first common drain line is connected to the drains of the first and second transistors. The second common drain line is connected to the drains of the third and fourth transistors. The detecting circuit detects that the first and second common drain lines are non-conducting.

The nonvolatile semiconductor memory device has a typical configuration of a four-value flash memory. In this case, a good sector code read from a nonvolatile memory cell onto a bit line pair is latched by, not the sense latch, but the first and second data latches. When the good sector code is latched by the first data latch, all the first to fourth transistors are turned off, and the first and second common drain lines are made non-conducting. Therefore, when the non-conduction of the first and second common drain lines is detected by the detecting circuit, the nonvolatile memory cell can be determined as a good cell.

According to further another aspect of the invention, a nonvolatile semiconductor memory device has a plurality of nonvolatile memory cells, a plurality of bit line pairs, a plurality of sense latches, a plurality of first data latches, a plurality of second data latches, and a plurality of first and second transistors. The plurality of pairs of bit lines are connected to the plurality of nonvolatile memory cells. The plurality of sense latches are provided in correspondence with the plurality of pairs of bit lines. Each of the sense latches has a first input node connected to one of bit lines of a corresponding bit line pair and a second input node connected to the other bit line of the corresponding bit line pair. The plurality of first data latches are provided in correspondence with bit lines each of which is one of bit lines of each of the plurality of bit line pairs. Each of the first data latches has an input node connected to the corresponding one of bit lines. The plurality of second data latches are provided in correspondence with the other bit lines of the plurality of bit line pairs. Each of the second data latches has an input node connected to the corresponding other bit line. The plurality of first and second transistors are provided in correspondence with two or more sense latches out of the plurality of sense latches. The gate of each of the first transistors is connected to a first input node of a corresponding sense latch and the gate of each of the second transistors is connected to a second input node of a corresponding sense latch. The nonvolatile semiconductor memory device further has a first common drain line, a second common drain line, and a detecting circuit. The first common drain line is connected to the drains of the first transistors. The second common drain line is connected to the drains of the second transistors. The detecting circuit detects that the first and second common drain lines are non-conducting.

The nonvolatile semiconductor memory device also has a typical configuration of a four-value flash memory. In this case, a good sector code read from a nonvolatile memory cell and output to a bit line pair is latched by, not the first and second data latches, but the sense latch. When the good sector code is latched by the sense latch, all the first and second transistors are turned off, and the first and second common drain lines are made non-conducting. Therefore, when the non-conduction of the first and second common drain lines is detected by the detecting circuit, the nonvolatile memory cell can be determined as a good cell.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a block diagram showing a general configuration of a flash memory according to a first embodiment of the invention;

FIG. 2 is a circuit diagram showing the configuration of a memory cell array, a data register, a column selecting circuit, and a data determining circuit in FIG. 1;

FIG. 3 is a block diagram showing main components of the data determining circuit in FIG. 1;

FIG. 4 is a circuit diagram showing the configuration of one of current sense amplifiers in FIG. 2 or 3;

FIG. 5 is a circuit diagram showing the configuration of the other current sense amplifier in FIG. 2 or 3;

FIG. 6 is a circuit diagram showing main components of a flash memory according to a second embodiment of the invention;

FIG. 7 is a circuit diagram showing the configuration of a current sense amplifier in FIG. 6;

FIG. 8 is a circuit diagram showing main components of a flash memory according to a third embodiment of the invention;

FIG. 9 is a circuit diagram showing main components of a flash memory according to a fourth embodiment of the invention;

FIG. 10 is a circuit diagram showing main components of a four-value flash memory according to a fifth embodiment of the invention;

FIG. 11 is a circuit diagram showing main components of a four-value flash memory according to a sixth embodiment of the invention;

FIG. 12 is a circuit diagram showing main components of a flash memory according to a seventh embodiment of the invention;

FIG. 13 is a block diagram showing a general configuration of a conventional flash memory;

FIG. 14 is a circuit diagram showing main components of a binary flash memory;

FIG. 15 is a diagram showing a threshold distribution of binary memory cells illustrated in FIG. 14;

FIG. 16 is a circuit diagram showing main components of a four-value flash memory;

FIG. 17 is a diagram showing a threshold distribution of four-value memory cells illustrated in FIG. 16;

FIG. 18 is an address map showing one sector in which a good sector code is written; and

FIG. 19 is a flowchart showing a conventional method of reading a good sector code and determining whether each of sectors is good or not.

### DESCRIPTION OF THE PREFERRED EMBODIMENTS

Embodiments of the invention will be described in detail hereinbelow with reference to the drawings. The same or corresponding components are designated by the same reference numeral and the description will not be repeated.

### First Embodiment

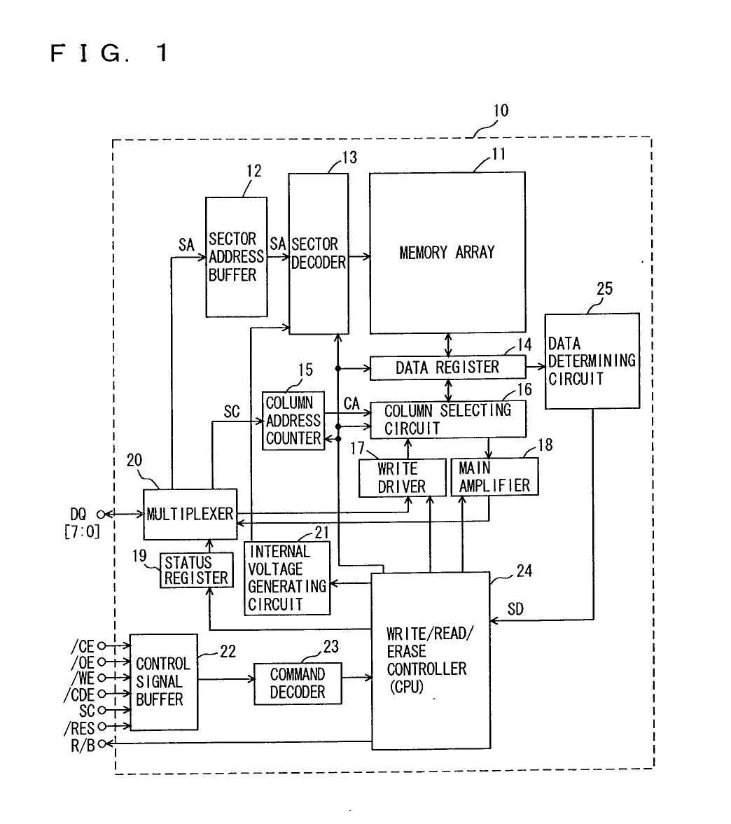

FIG. 1 is a block diagram showing a general configuration of a binary flash memory according to a first embodiment of the invention. Referring to FIG. 1, a flash memory 10 includes a memory array 11, a sector address buffer 12, a sector decoder 13, a data register 14, a column address counter 15, a column selecting circuit 16, a write driver 17, a main amplifier 18, a status register 19, a multiplexer 20, an internal voltage generating circuit 21, a control signal buffer 22, a command decoder 23, a write/read/erase controller 24, and a data determining circuit 25.

Memory array 11 includes a plurality of nonvolatile memory cells (not shown) arranged in a matrix, a plurality of word lines (not shown) arranged in rows, and a plurality of bit line pairs (not shown) arranged in columns. Each word line is connected to a plurality of nonvolatile memory cells disposed in a corresponding row. Each bit line pair is connected to a plurality of nonvolatile memory cells disposed in a corresponding column. In this case, the plurality of nonvolatile memory cells connected to one word line construct one sector. Sector decoder 13 selects a sector in memory array 11 in response to a sector address signal SA. Data register 14 latches data of one sector read from memory array 11. Column address counter 15 generates a column address CA in response to a serial clock signal SC for reading. Column selecting circuit 16 includes a plurality of column selection gates (not shown) provided in correspondence with a column in memory array 11 and a column decoder (not shown) for selectively turning on a column selection gate in response to column address CA. Write driver 17 supplies data DQ[7:0] input from the outside to column selecting circuit 16. Main amplifier 18 outputs data DQ[7:0] read from column selecting circuit 16 to the outside. Status register 19 holds the status of flash memory 10, such as a write, read, or erase status. Multiplexer 20 routes an address and data in accordance with the status held in status register 19. For example, in the case of the write status, multiplexer 20 supplies sector address SA to which data is to be written to sector decoder 13 via sector address buffer 12, and supplies data DQ[7:0] to be written to the sector address to write driver 17. In the case of the read status, multiplexer 20 supplies sector address SA from which data is to be read to sector decoder 13 via sector address buffer 12 and outputs data DQ[7:0] read from the sector and amplified by main amplifier 18 to the outside. Internal voltage generating circuit 21 generates an internal voltage higher than the source voltage and supplies the internal voltage to sector decoder 13. Sector decoder 13 supplies the given internal voltage to a word line. Control signal buffer 22 receives control signals such as a chip enable signal /CE, an output enable signal /OE, a write enable signal /WE, a command data enable signal /CDE, a serial clock signal SC, and a reset signal /RES. Command decoder 23 decodes a command in response to a control signal received from the outside via control signal buffer 22. Write/read/erase controller 24 consists of a CPU (Central Processing Unit) and controls sector decoder 13, data register 14, column address counter 15, column selecting circuit 16, write driver 17, main amplifier 18, status register 19, and internal voltage generating circuit 21 so as to perform a writing, reading, or erasing operation in accordance with a command from command decoder 23. Controller 24 also outputs a ready/busy signal R/B to the outside. Data determining circuit 25 determines whether data register 14 latches predetermined data or not.

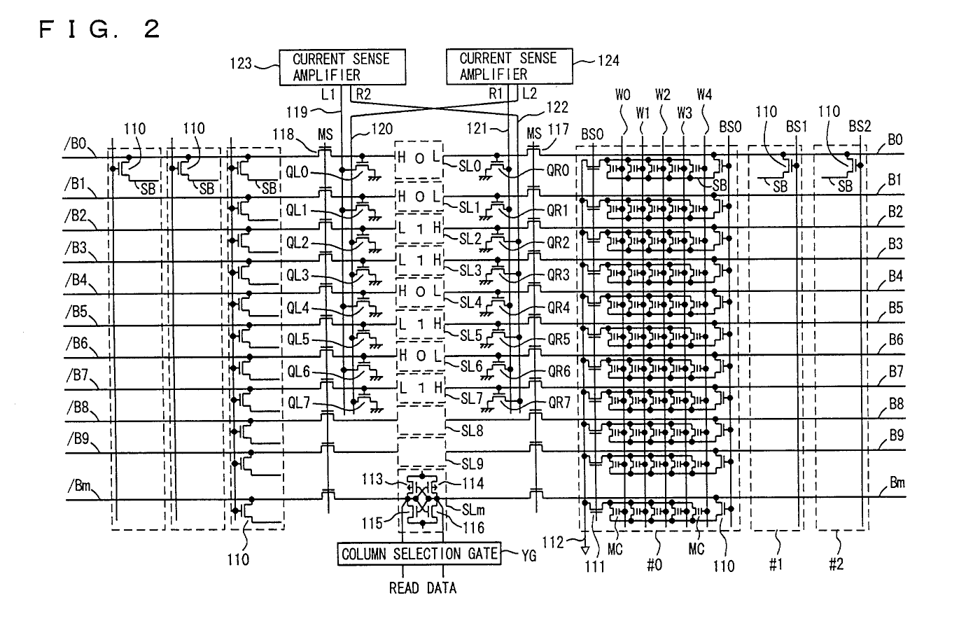

FIG. 2 is a circuit diagram showing the configuration of memory array 11, data register 14, column selecting circuit 16, and data determining circuit 25 in FIG. 1.

Memory array 11 includes, as shown in FIG. 2, a plurality of binary nonvolatile memory cells MC arranged in a matrix, a plurality of word lines W0 to W4 arranged in rows, and a plurality of bit line pairs B0, /B0 to Bm, /Bm arranged in columns. Each nonvolatile memory cell MC consists of a floating gate type N-channel MOS transistor. Each of word lines W0 to W4 is connected commonly to control gates of a plurality of memory cells MC disposed in a corresponding row. Bit line pairs B0, /B0 to Bm, /Bm are so called open bit line pairs. Bit lines B0 to Bm are disposed linearly together with bit lines /B0 to /Bm, respectively.

Memory array 11 is divided into a plurality of blocks #0 to #2. Each of blocks #0 to #2 includes a plurality of sub bit lines SB arranged in columns, and a plurality of block selection gates 110 and 111 provided in correspondence with sub bit lines SB. Each sub bit line SB is connected to the drains of corresponding memory cells MC. Each block selection gate 110 is connected between corresponding one of bit lines B0 to Bm and /B0 to /Bm and a corresponding sub bit line SB. Each block selection gate 111 is connected between the sources of corresponding memory cells MC and a common source line 112. Block selection gates 110 and 111 are turned on in response to block selection signals BS0 to BS2.

Data register 14 includes a plurality of sense latches SL0 to SLm provided in correspondence with plurality of bit line pairs B0, /B0 to Bm, /Bm, respectively. Each sense latch SLi (i=0 to m) includes P-channel MOS transistors 113 and 114 and N-channel MOS transistors 115 and 116 which are cross coupled and is connected to corresponding bit lines Bi and /Bi (i=0 to m). Each sense latch SLi amplifies a potential difference between corresponding bit lines Bi and /Bi.

Column selecting circuit 16 includes a plurality of column selection gates YG provided in correspondence with plurality of sense latches SL0 to SLm. Each column selection gate YG is connected to corresponding sense latch SLi. Column selecting circuit 16 therefore selectively reads data latched in data register 14 in response to column address signal CA.

Between bit lines B0 to Bm and sense latches SL0 to SLm, a plurality of memory selection gates 117 are connected. Between bit lines /B0 to /Bm and sense latches SL0 to SLm, a plurality of memory selection gates 118 are connected. Memory selection gates 117 and 118 are turned on in response to a memory selection signal MS.

In flash memory 10, N-channel MOS transistors QR0 to QR7 are further provided in correspondence with sense latches SL0 to SL7, respectively. The source of each of transistors QRj (j=0 to 7) is grounded and the gate is connected to one of input nodes of corresponding sense latch SLj (j=0 to 7). Transistors QL0 to QL7 are also provided in correspondence with sense latches SL0 to SL7, respectively. The source of each transistor QLj (j=0 to 7) is grounded and the gate is connected to the other input node of corresponding sense latch SLj.

The drains of transistors QL0, QL1, QL4, and QL6 are connected to a common drain line 119. The drains of transistors QL2, QL3, QL5, and QL7 are connected to a common drain line 120. The drains of transistors QR0, QR1, QR4, and QR6 are connected to a common drain line 121. The drains of transistors QR2, QR3, QR5, and QR7 are connected to a common drain line 122.

Common drain lines 119 and 122 are connected to a current sense amplifier 123. Common drain lines 120 and 121 are connected to a current sense amplifier 124.

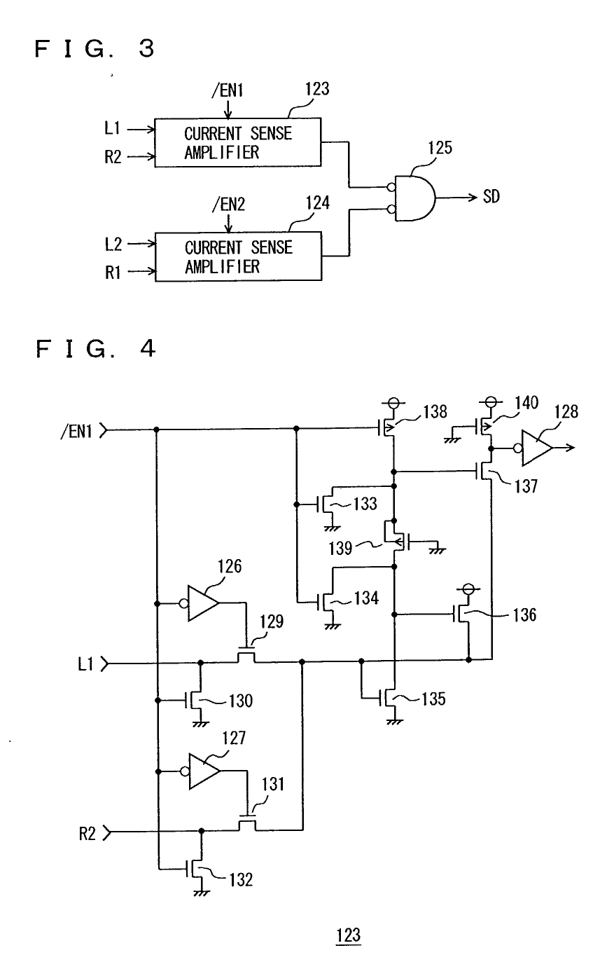

FIG. 3 is a block diagram showing the configuration of a part of data determining circuit 25 in FIG. 1. As shown in FIG. 3, data determining circuit 25 includes, in addition to transistors QR0 to QR7 and QL0 to QL7 and common drain lines 119 to 122 illustrated in FIG. 2, current sense amplifiers 123 and 124 and an NOR (negative logic) circuit 125.

FIG. 4 is a circuit diagram showing the configuration of current sense amplifier 123 in FIG. 2 or 3. As shown in FIG. 4, current sense amplifier 123 includes inverters 126 to 128, N-channel MOS transistors 129 to 137, and P-channel MOS transistors 138 to 140. When enable signal /EN is at the H (logical high) level, transistors 130, 132, 133, and 134 are turned on, and transistors 129, 131, and 138 are turned off. Transistors 135, 136, and 137 are therefore turned off. Since the input of inverter 128 is pulled up to the source voltage by transistor 140, an L (logical low) level signal is output.

On the other hand, when enable signal /EN1 is at the L level, transistors 129, 131, and 138 are turned on and transistors 130, 132, 133, and 134 are turned off. Consequently, transistor 137 is turned on. When both levels L1 and R2 of common drain lines 119 and 122 are the ground voltage, transistors 135 and 136 are turned off. As a result, the ground voltage is supplied to inverter 128 via transistor 137, and an H level signal is output. On the other hand, when both common drain lines 119 and 122 are in a high impedance state, the source voltage is supplied to inverter 128 via transistor 140, and an L level signal is output.

In short, current sense amplifier 123 is made active when enable signal /EN1 is at the L level, outputs the H level signal when both levels L1 and R2 of common drain lines 119 and 122 are the ground voltage, and outputs the L level signal when both common drain lines 119 and 122 are in the high impedance state (non-conductive state). Current sense amplifier 123 is made inactive when enable signal /EN1 is at the H level and always outputs the L level signal irrespective of levels L1 and R2 of common drain lines 119 and 122.

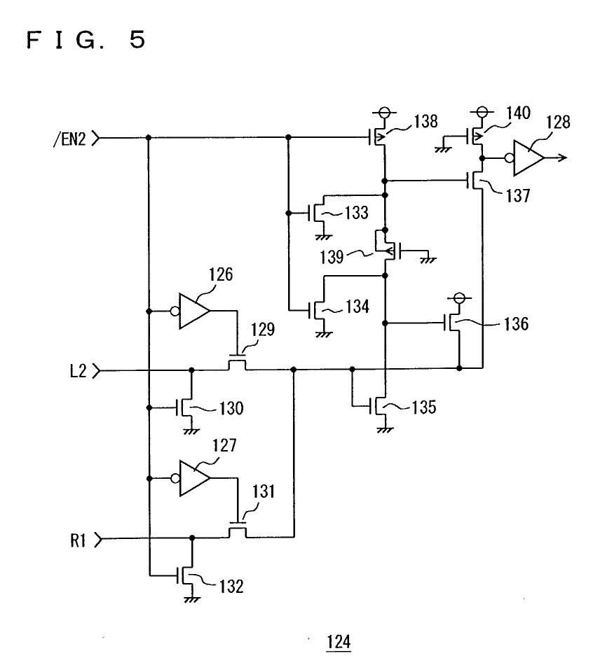

FIG. 5 is a circuit diagram showing the configuration of current sense amplifier 124 in FIG. 2 or 3. As shown in FIG. 5, current sense amplifier 124 has the configuration similar to that of current sense amplifier 123 shown in FIG. 4 except that current sense amplifier 124 receives level L2 of common drain line 120 in place of level L1 of common drain line 119, and receives level L2 of common drain line 120 in place of level R2 of common drain line 122. Current sense amplifier 124 receives enable signal /EN2 in place of enable signal /EN1.

Therefore, current sense amplifier 124 is made active when enable signal /EN2 is at the L level, outputs the H level signal when levels L2 and R1 of common drain lines 120 and 121 are the ground voltage, and outputs the L level signal when both common drain lines 120 and 121 are in the high impedance state (non-conductive state). Current sense amplifier 124 is made inactive when enable signal /EN1 is at the H level and always outputs an L level signal irrespective of levels L2 and R1 of common drain lines 120 and 121.

An operation of determining whether a sector is good or not by the flash memory will now be described. In this case, a plurality of memory cells MC connected to each of word lines W0 to W4 construct one sector. In order to present whether each of sectors is good or not to the user, the manufacturer of the flash memory writes a predetermined good sector code in a predetermined column address in each sector at the time of shipment of the product. In this case, “ACh (h denotes that its preceding number is a hexadecimal digit)” is written in eight memory cells MC connected to bit lines B0 to B7 or /B0 to /B7. For example, when the sector corresponding to word line W0 is good, “1” is written in memory cell MC connected to word line W0 and bit line B7, “0” is written to memory cell MC connected to word line W0 and bit line B6, “1” is written in memory cell MC connected to word line W0 and bit line B5, “0” is written in memory cell MC connected to word line W0 and bit line B4, “1” is written in memory cell MC connected to word line W0 and bit line B3, “1” is written in memory cell MC connected to word line W0 and bit line B2, “1” is written in memory cell MC connected to word line W0 and bit line B1, and “0” is written in memory cell MC connected to word line W0 and bit line B0.

The user enters a read command for determining whether each of the sectors is good or not to flash memory 10. Command decoder 23 decodes the entered read command. According to the decoded read command, controller 24 executes a reading operation.

Concretely, memory selection signal MS goes high and the bit line pairs B0, /B0 to Bm, /Bm are connected to sense latches SL0 to SLm, respectively. Subsequently, block selection signals BS0 to BS2 sequentially go high and blocks #0 to #2 are sequentially selected.

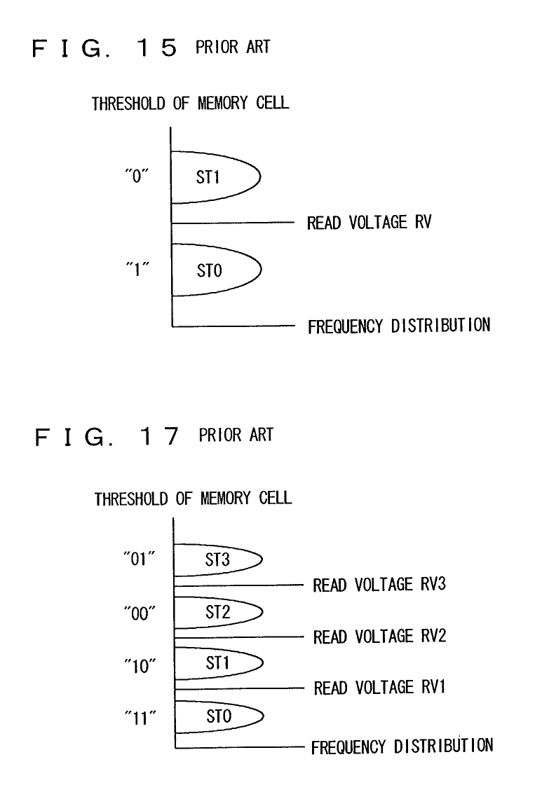

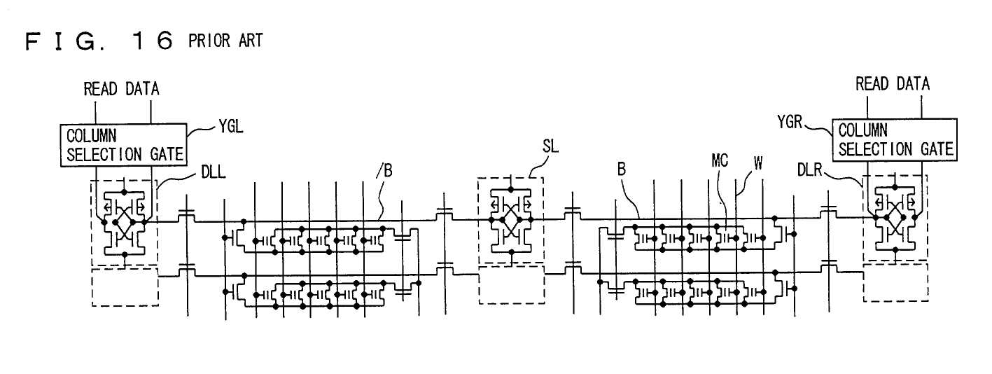

When block #0 is selected, sector decoder 13 sequentially supplies read voltage RV shown in FIG. 15 to word lines W0 to W4.

For example, in the case where the sector corresponding to word line W0 is good, when read voltage RV is supplied to word line W0, sense latch SL7 latches “1”, sense latch SL6 latches “0”, sense latch SL 5 latches “1”, sense latch SL4 latches “0”, sense latch SL3 latches “1”, sense latch SL2 latches “1”, sense latch SL1 latches “0”, and sense latch SL0 latches “0”. Consequently, all the input nodes on the right side in the drawing of sense latches SL0, SL1, SL4, and SL6 are set to the L level. All the input nodes on the left side in the drawing of sense latches SL2, SL3, SL5, and SL7 are set to the L level. Consequently, all transistors QR0, QR1, QR4, and QR6 connected to common drain line 121 are turned off, and all transistors QL2, QL3, QL5, and QL7 connected to common drain line 120 are turned off. As a result, both common drain lines 120 and 121 enter a high impedance state (non-conductive state). Current sense amplifier 124 detects that common drain lines 120 and 121 are non-conductive. Specifically, enable signal /EN1 goes high and enable signal /EN2 goes low, so that current sense amplifier 123 is made inactive, and current sense amplifier 124 is made active. An L-level signal is therefore output from both current sense amplifiers 123 and 124, and a sector status determination signal at the H level indicating that the sector is good is output from data determining circuit 25 (to be specific, NOR circuit 125).

On the other hand, when the sector is bad, the good sector code “ACh” is not written, so that levels L2 and R1 of common drain lines 120 and 121 become the ground voltage. The H-level signal is therefore output from current sense amplifier 124. As a result, the sector status determination signal at the L level indicating that the sector is bad is output from data determining circuit 25.

Controller 24 writes sector status determination signal SD to status register 19. Sector status determination signal SD is output to the outside via multiplexer 20. The user can determine whether the sector is good or not on the basis of sector status determination signal SD which is output.

In the case of determining whether each of the sectors on the left side in the drawing of sense latches SL1 to SLm is good or not, it is sufficient to detect the non-conductive state of common drain lines 119 and 122 by current sense amplifier 123 for the following reason. In the case where the good sector code is read from a sector on the left side, all transistors QL0, QL1, QL4, and QL6 connected to common drain line 119 are turned off, and all transistors QR2, QR3, QR5, and QR 7 connected to common drain line 122 are turned off.

According to the first embodiment as described above, transistors QR0 to QR7 and QL0 to QL7 are provided to determine whether the good sector code is latched by sense latches SL0 to SL7 or not. Thus, without outputting the good sector code to the outside as in the conventional technique, the status of each sector can be determined.

Although the good sector code “ACh” of one byte is used in the embodiment, any good sector codes may be used. The good sector code of any bytes may be used. In the case of using a good sector code different from the above, the drains of transistors QR0 to QR7 and QL0 to QL7 may be connected to common drain lines 119 to 122 in a manner according to the code. In the case of using a good sector code of a few bytes, it may provide transistors in accordance with the number of bytes.

It is also possible to detect the good sector code “53h” in the connection manner of transistors QR0 to QR7 and QL0 to QL7 shown in FIG. 2. When good sector code “53h” is read from the sectors on the right side of sense latches SL0 to SLm, sense latch SL7 latches “0”, sense latch SL6 latches “1”, sense latch SL5 latches “0”, sense latch SL4 latches “1”, sense latch SL3 latches “0”, sense latch SL2 latches “0”, sense latch SL1 latches “1”, and sense latch SL0 latches “1”. As a result, all transistors QL0, QL1, QL4, and QL6 connected to common drain line 119 are turned off, and all transistors QR2, QR3, QR5, and QR7 connected to common drain line 122 are turned off, so that current sense amplifier 123 can detect that common drain lines 119 and 122 are non-conductive.

### Second Embodiment

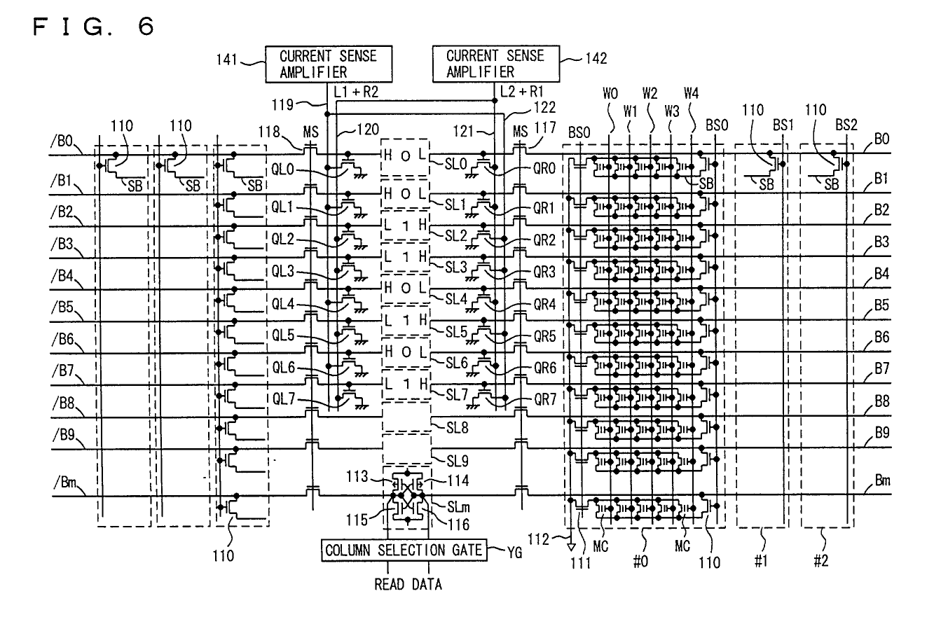

The configuration of a second embodiment shown in FIG. 6 which is different from the first embodiment shown in FIG. 2 may be also used. In the configuration, common drain lines 119 and 122 are connected to each other and also connected to a current sense amplifier 141, and common drain lines 120 and 121 are connected to each other and also connected to a current sense amplifier 142.

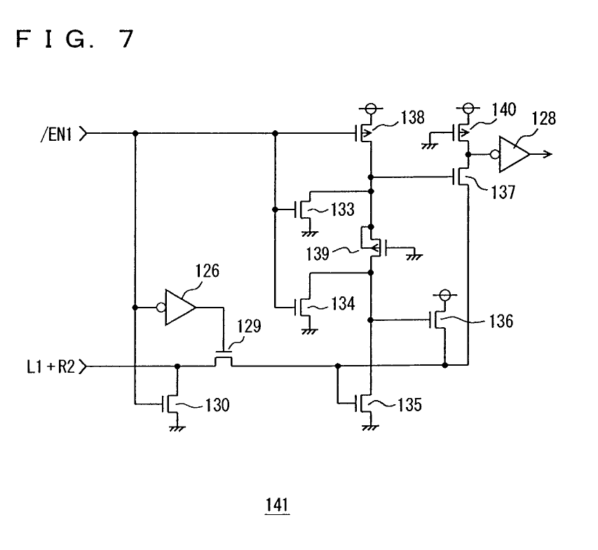

FIG. 7 is a circuit diagram showing the configuration of current sense amplifier 141 in FIG. 6. As shown in FIG. 7, current sense amplifier 141 does not have inverter 127 and transistors 131 and 132 illustrated in FIG. 4. According to current sense amplifier 141, when enable signal /EN1 is at the L level and both common drain lines 119 and 122 are non-conductive, an L-level signal is output. Current sense amplifier 142 has the same configuration as that of current sense amplifier 141 shown in FIG. 7. In the second embodiment, in place of current sense amplifiers 123 and 124 in the first embodiment, such current sense amplifiers 141 and 142 are used.

### Third Embodiment

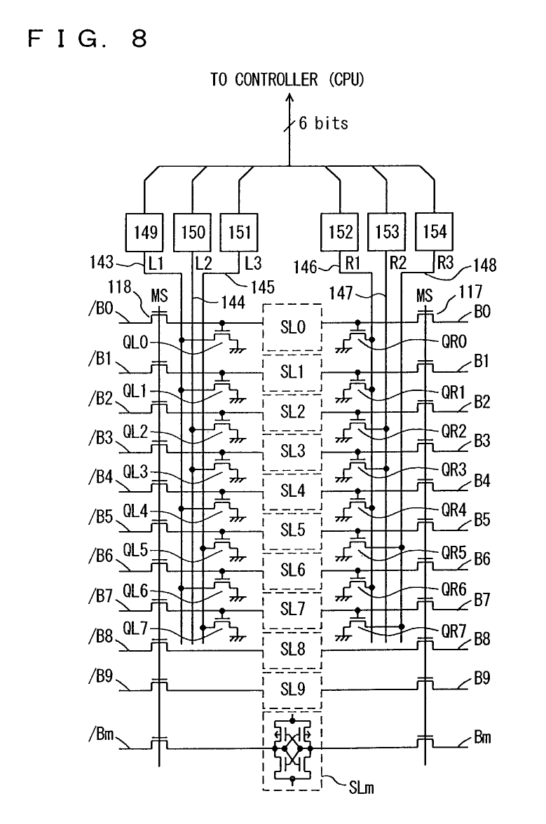

FIG. 8 is a circuit diagram showing main components of a flash memory according to a third embodiment of the invention. In the third embodiment, as shown in FIG. 8, three common drain lines 143 to 145 are provided on the left side in the drawing of sense latches SL0 to SLm. Further, three common drain lines 146 to 148 are provided on the left sides in the drawing of sense latches SL0 to SLm. The drains of transistors QL0, QL1, QL4, and QL6 are connected to common drain line 143. The drains of transistors QL2 and QL3 are connected to common drain line 144. The drains of transistors QL5 and QL7 are connected to common drain line 145. The drains of transistors QR0, QR1, QR4, and QR6 are connected to common drain line 146. The drains of transistors QR1 and QR3 are connected to common drain line 147. The drains of transistors QR5 and QR7 are connected to common drain line 148.

A data determining circuit in the third embodiment includes transistors QL0 to QL7 and QR0 to QR7, common drain lines 143 to 148, and current sense amplifiers 149 to 154. Common drain lines 143 to 145 are connected to current sense amplifiers 149 to 151, respectively. Common drain lines 146 to 148 are connected to current sense amplifiers 152 to 154, respectively. Each of current sense amplifiers 149 to 154 has the same configuration as that of current sense amplifier 141 shown in FIG. 7.

In the first and second embodiments, in the case of reading the good sector code from the sectors on the right side in the drawing of sense latches SL0 to SLm, only whether the good sector code is “ACh” or not can be determined. In contrast, according to the third embodiment, six kinds of good sector codes can be determined.

The following Table 1 is a truth table showing good sector codes which can be determined in the third embodiment.

TABLE 1

| | R1, | R1, | R1, | L1, | L1, | L1, |
|---|---|---|---|---|---|---|
| | L2, L3 | R2, L3 | L2, R3 | L2, R3 | R2, L3 | R2, R3 |
| SL0 | 0 | 0 | 0 | 1 | 1 | 1 |
| SL1 | 0 | 0 | 0 | 1 | 1 | 1 |
| SL2 | 1 | 0 | 1 | 1 | 0 | 0 |
| SL3 | 1 | 0 | 1 | 1 | 0 | 0 |
| SL4 | 0 | 0 | 0 | 1 | 1 | 1 |
| SL5 | 1 | 1 | 0 | 0 | 1 | 0 |
| SL6 | 0 | 0 | 0 | 1 | 1 | 1 |
| SL7 | 1 | 1 | 0 | 0 | 1 | 0 |
| hexadecimal | AC | A0 | 0C | 5F | F3 | 53 |

In the case of determining the good sector code of “ACh”, only current sense amplifiers 152, 150, and 151 are activated. When good sector code “ACh” is latched by sense latches SL7 to SL0, common drain lines 146, 144, and 145 are made non-conductive. Consequently, the H-level signal is output from all current sense amplifiers 149 to 154 to controller 24.

In the case of determining the good sector code of “A0h”, only current sense amplifiers 152, 153, and 151 are activated. When good sector code “A0h” is latched by sense latches SL7 to SL0, common drain lines 146, 147, and 145 are made non-conductive. The H-level signal is consequently output from all current sense amplifiers 149 to 154 to controller 24.

In the case of determining the good sector code of “0Ch”, only current sense amplifiers 152, 150, and 154 are activated. When good sector code “0Ch” is latched by sense latches SL7 to SL0, common drain lines 146, 144, and 148 are made non-conductive. The H-level signal is consequently output from all current sense amplifiers 149 to 154 to controller 24.

In the case of determining the good sector code of “5Fh”, only sense amplifiers 149, 150, and 154 are activated. When good sector code “5Fh” is latched by sense latches SL7 to SL0, common drain lines 143, 144, and 148 are made non-conductive. The H-level signal is consequently output from all current sense amplifiers 149 to 154 to controller 24.

In the case of determining good sector code of “F3h”, only current sense amplifiers 149, 153, and 151 are activated. When good sector code “F3h” is latched by sense latches SL7 to SL0, common drain lines 143, 147, and 145 are made non-conductive. The H-level signal is consequently output from all current sense amplifiers 149 to 154 to controller 24.

In the case of determining the good sector code of “53h”, only current sense amplifiers 149, 153, and 154 are activated. When good sector code “53h” is latched by sense latches SL7 to SL0, common drain lines 143, 147, and 148 are made non-conductive. The H-level signal is consequently output from all current sense amplifiers 149 to 154 to controller 24.

As described above, according to the third embodiment, six good sector codes can be determined with respect to the sectors on the right side in the drawing of sense latches SL0 to SLm.

Although three common drain lines are provided on each of both sides of sense latches SL0 to SLm in the third embodiment, when the number of common drain lines is increased, the number of kinds of good sector codes also increases.

### Fourth Embodiment

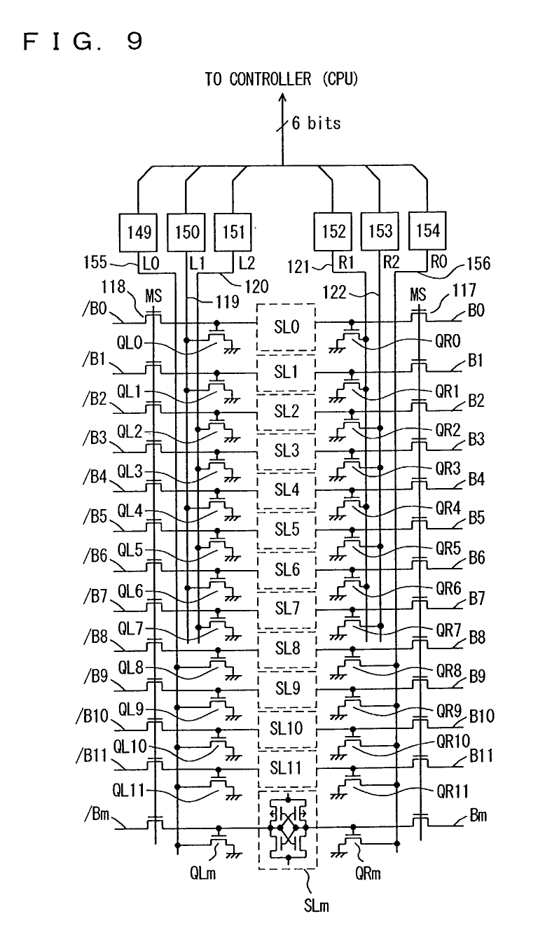

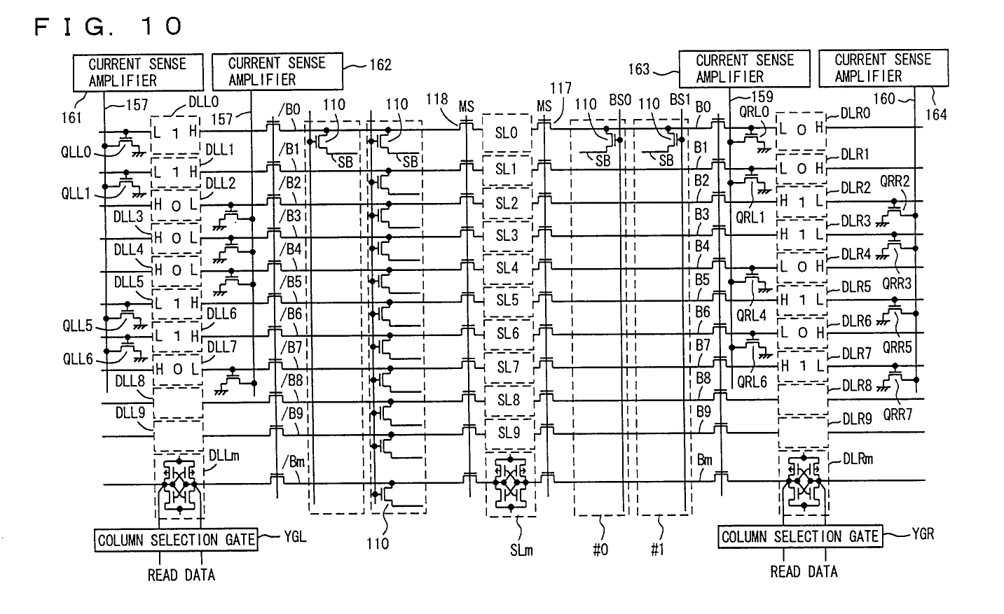

FIG. 9 is a circuit diagram showing main components of a flash memory according to a fourth embodiment of the invention. In the fourth embodiment, a determining circuit for the good sector code also serves as a determining circuit for verification.

As shown in FIG. 9, the drains of transistors QL0, QL1, QL4, and QL6 are connected to common drain line 119. The drains of transistors QL2, QL3, QL5, and QL7 are connected to common drain line 120. The drains of transistors QR0, QR1, QR4, and QR6 are connected to common drain line 121. The drains of transistors QR2, QR3, QR5, and QR7 are connected to common drain line 122.

In the flash memory, in correspondence with sense latches SL8 to SLm, N-channel MOS transistors QL8 to QLm are provided on the left side in the drawing, and N-channel MOS transistors QR8 to QRm are provided on the right side. The gates of transistors QL8 to QLm are connected to input nodes on the left side in the drawing of sense latches SL8 to SLm, respectively. The sources of transistors QL8 to QLm are grounded. The drains of transistors QL8 to QLm are connected to a common drain line 155. The gates of transistors QR8 to QRm are connected to input nodes on the right side in the drawing of sense latches SL8 to SLm, respectively. The sources of transistors QR8 to QRm are grounded. The drains of transistors QR8 to QRm are connected to a common drain line 156.

Table 2 is a truth table indicating a sector status determining operation and a verifying operation by the flash memory.

TABLE 2

| | | R1, | L1, | | |
|---|---|---|---|---|---|
| | R1, L2 | R2, R0 | L2, L0 | | |
| SL0 | 0 | 0 | 1 | | |
| SL1 | 0 | 0 | 1 | | |
| SL2 | 1 | 0 | 1 | | |
| SL3 | 1 | 0 | 1 | | |
| SL4 | 0 | 0 | 1 | {close oversize parenthesis} | code determination area |
| SL5 | 1 | 0 | 1 | | |
| SL6 | 0 | 0 | 1 | | |
| SL7 | 1 | 0 | 1 | | |
| SL8 | — | 0 | 1 | | |
| SL9 | — | 0 | 1 | | |
| SL10 | — | 0 | 1 | | |
| SL11 | — | 0 | 1 | | |
| . | . | . | . | | |
| . | . | . | . | | |
| . | . | . | . | | |
| SLm | — | 0 | 1 | | |

In the case of determining whether or not good sector code “ACh” is written in the sectors on the right side in the drawing of sense latches SL0 to SLm, only current sense amplifiers 152 and 151 are activated. Good sector code “ACh” is read from the sectors and latched by sense latches SL7 to SL0, and common drain lines 121 and 120 are made nonconductive. Consequently, the H-level signal is output from all current sense amplifiers 149 to 154.

In the case of writing data of “0” to all the sectors on the right side in the drawing of sense latches SL0 to SLm and verifying the data, only current sense amplifiers 152, 153, and 154 are activated. When the data of “0” is read from all the sectors and latched by sense latches SL0 to SLm, all transistors QR0 to QRm are turned off. It makes common drain lines 121, 122, and 156 nonconductive. Consequently, the H-level signal is output from all current sense amplifiers 149 to 154. On the other hand, for example, when data of “1” is erroneously written in memory cells connected to bit line B4, transistor QR4 is turned on and the level R1 of common drain line 121 becomes the ground voltage. Consequently, the L-level signal is output only from current sense amplifier 152.

In the case of writing data of “1” in all of sectors on the right side in the drawing of sense latches SL0 to SLm and verifying the data, or eliminating the data in a sector and verifying it, only current sense amplifiers 149, 150, and 151 are activated. When data of “1” is read from all of sectors and latched by sense latches SL0 to SLm, all transistors QL0 to QLm are turned off, and common drain lines 119, 120, and 155 are made nonconductive. Consequently, the H-level signal is output from all current sense amplifiers 149 to 154. On the other hand, when data of “0” is erroneously written in the memory cells connected to bit line B4 or data in the memory cells is not erased, transistor QL4 is turned on, and the level L1 of common drain line 119 becomes the ground voltage. Consequently, the L-level signal is output only from current sense amplifier 150.

According to the fourth embodiment as described above, transistors QL8 to QLm and QR8 to QRm are added and data of sense latches SL0 to SLm is detected, writing and erasing can be verified. Moreover, since transistors QL0 to QL7 and QR0 to QR7 for determining good sector code also serve as transistors for verifying writing and erasing operation, an increase in the layout area necessary for the transistors for determination can be suppressed.

### Fifth Embodiment

FIG. 10 is a circuit diagram showing main components of a four-value flash memory according to a fifth embodiment of the invention. The invention can be applied not only to the binary flash memory but also to a four-value flash memory as shown in FIG. 10. As illustrated in FIG. 10, the four-value flash memory has, in addition to sense latches SL0 to SLm, data latches DLL0 to DLLm and DLR0 to DLRm for latching data transferred from sense latches SL0 to SLm. Data latches DLR0 to DLRm are connected to bit lines B0 to Bm, respectively. Data latches DLL0 to DLLm are connected to bit lines /B0 to /Bm. In this case, data latches DLL0 to DLLm and DLR0 to DLRm construct data register 14 in FIG. 1. In the four-value flash memory, data sensed and latched by sense latches SL0 to SLm in the center is transferred to data latches DLL0 to DLLm and DLR0 to DLRm on both sides, and two-bit data selected by column selection gates YGL and YGR is output.

In the fifth embodiment, N-channel MOS transistors QLL0, QLL1, QLR2 to QLR4, QLL5, QLL6, and QLR7 are provided on both sides of data latches DLL0 to DLL7. N-channel MOS transistors QRL0, QRL1, QRR2, QRR3, QRL4, QRR5, QRL6, and QRR7 are provided on both sides of data latches DLR0 to DLR7.

The gates of transistors QLL0, QLL1, QLL5, and QLL6 are connected to input nodes on the left side in the diagram of data latches DLL0, DLL1, DLL5, and DLL6, respectively. The gates of transistors QLR2 to QLR4 and QLR7 are connected to the input nodes on the right side in the diagram of data latches DLL2 to DLL4 and DLL7, respectively. The sources of transistors QLL0, QLL1, QLR2 to QLR4, QLL5, QLL6, and QLR7 are grounded. The drains of transistors QLL0, QLL1, QLL5, and QLL6 are connected to a common drain line 156. The drains of transistors QLR2 to QLR4, and QLR7 are connected to a common drain line 158.

On both sides of data latches DLR0 to DLR7, N-channel MOS transistors QRL0, QRL1, QRR2, QRR3, QRL4, QRR5, QRL6, and QRR7 are provided. The gates of transistors QRL0, QRL1, QRL4, and QRL6 are connected to input nodes on the left side in the drawing of data latches DLR0, DLR1, DLR4, and DLR6, respectively. The gates of transistors QRR2, QRR3, QRR5, and QRR7 are connected to input nodes on the right side in the diagram of data latches DLR2, DLR3, DLR5, and DLR7, respectively. The sources of transistors QRL0, QRL1, QRR2, QRR3, QRL4, QRR5, QRL6, and QRR7 are grounded. The drains of transistors QRL0, QRL1, QRL4, and QRL6 are connected to a common drain line 159. The; drains of transistors QRR2, QRR3, QRR5, and QRR7 are connected to a common drain line 160.

Common drain lines 157 to 160 are connected to current sense amplifiers 161 to 164, respectively. Each of current sense amplifiers 161 to 164 has the same configuration as that of current sense amplifier 141 shown in FIG. 7.

The first bit of the good sector code in each sector is latched by data latches DLL0 to DLL7, and the second bit is latched by data latches DLR0 to DLR7. All transistors QLL0, QLL1, QLR2 to QLR4, QLL5, and QLL6 are turned off, and all transistors QRL0, QRL1, QRR2, QRR3, QRL4, QRR5, QRL6, and QRR7 are turned off. Consequently, common drain lines 157 and 158 are made non-conductive and the H-level signal is output from current sense amplifiers 161 and 162. Common drain lines 159 and 160 are also made non-conductive, and the H-level signal is output also from current sense amplifiers 163 and 164.

According to the fifth embodiment as described above, in the four-value flash memory, transistors QLL0, QLL1, QLR2 to QLR4, QLL5, QLL6, QLR0, QLR1, QRR2, QRR3, QRL4, QRR5, QRL6, and QRR7 are provided, and whether data latches DLL0 to DLL7 and DLR0 to DLR7 latch the good sector code or not is determined. Consequently, whether a sector is good or not can be determined without outputting the good sector code to the outside.

The fifth embodiment can be also modified in accordance with the second to fourth embodiments.

### Sixth Embodiment

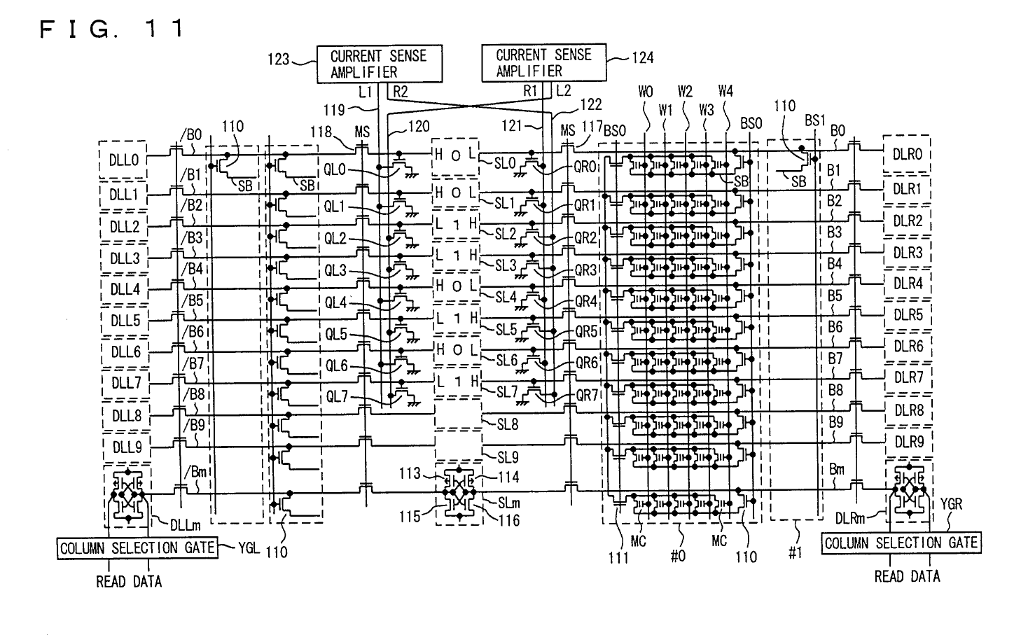

FIG. 11 is a circuit diagram showing main components of a four-value flash memory according to a sixth embodiment of the invention. In the sixth embodiment, in a manner similar to the first embodiment, transistors QL0 to QL7 and QR0 to QR7 are provided on both sides of sense latches SL0 to SL7.

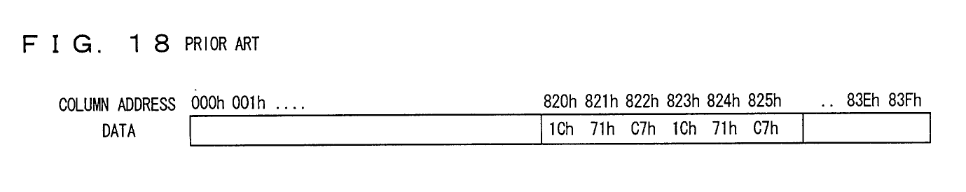

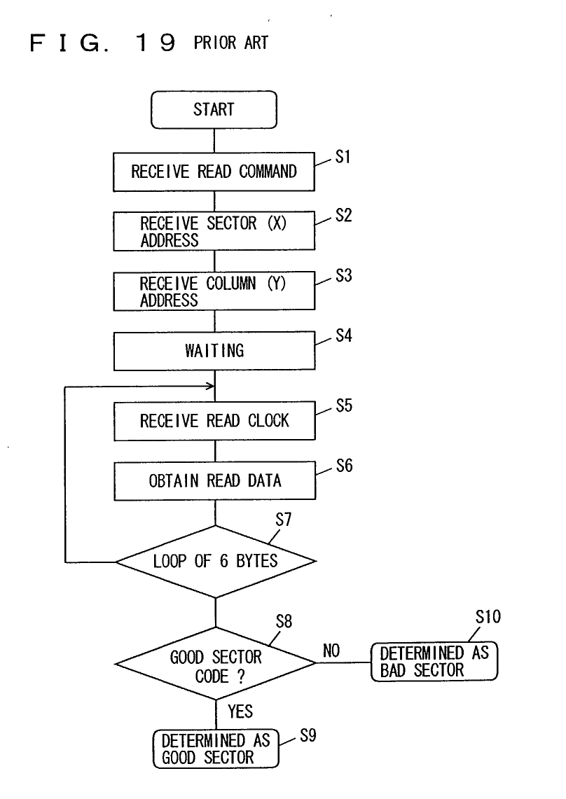

Usually, a four-value memory cell MC can hold one of four statuses ST0 to ST3 as shown in FIG. 17. In this case, whether memory cell MC holds the status ST0 or ST1, or the status ST2 or ST3 is determined. For example, when the good sector code is “ACh”, among good sectors, “01,” or “00” is written in memory cells MC connected to bit lines B0, B1, B4, and B6. “10” or “11” is written in memory cells connected to bit lines B2, B3, B5, and B7.

To determine whether each of the sectors is good or not, read voltage RV2 is supplied to each of word lines W0 to W4. From a good sector, good sector code “ACh” is read and latched by sense latches SL7 to SL0. Consequently, common drain lines 120 and 121 are made non-conductive and the H-level signal is output from current sense amplifier 124. According to the six embodiment as well, therefore, whether each of the sectors is good or not can be determined without outputting the good sector code to the outside.

The sixth embodiment can be modified according to the second to fourth embodiments.

### Seventh Embodiment

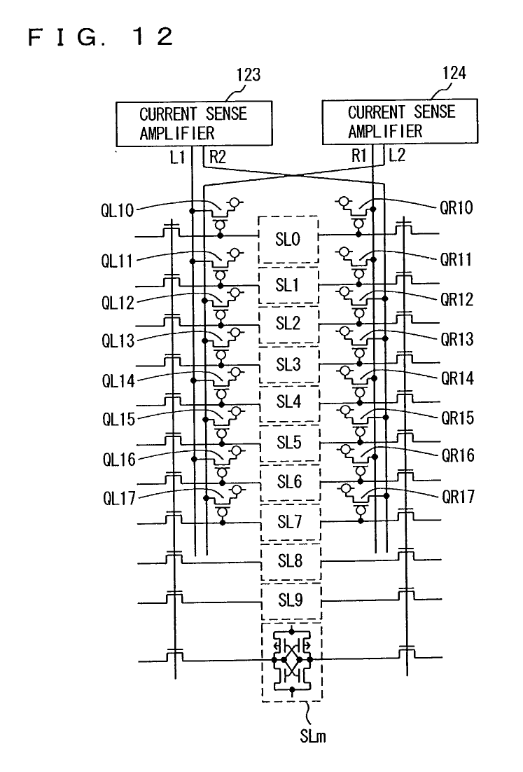

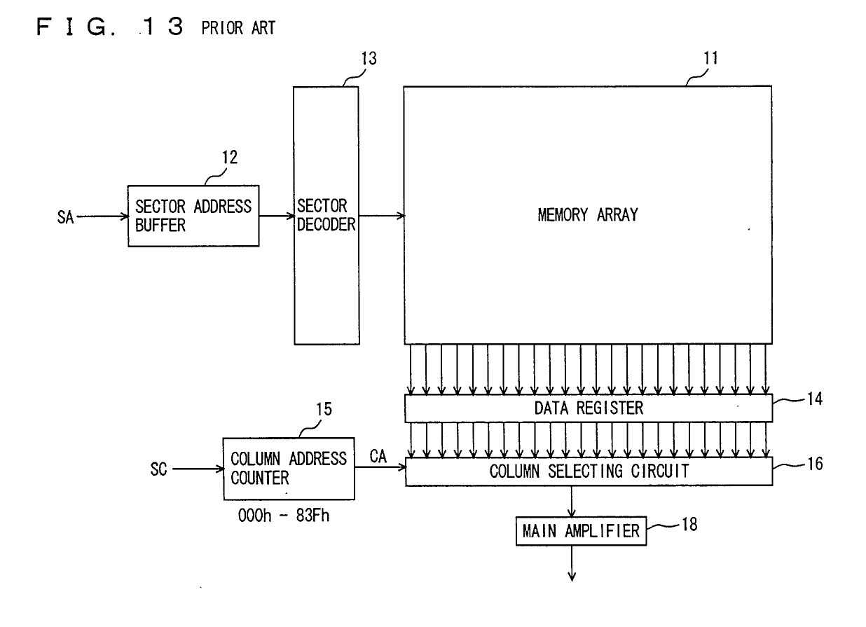

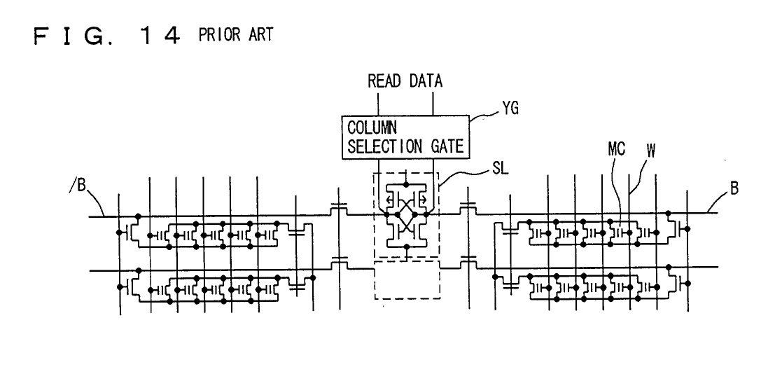

FIG. 12 is a circuit diagram showing main components of a flash memory according to a seventh embodiment of the invention. In place of N-channel MOS transistors QL0 to QL7 and QR0 to QR7 in the first embodiment shown in FIG. 2, P-channel MOS transistors QL10 to QL17 and QR10 to QR17 may be used. The sources of transistors QL10 to QL17 and QR10 to QR17 are connected to the source node. In this case, when a good sector code “53h (01010011)” is latched by sense latches SL7 to SL0, transistors QL12, QL13, QL15, QL17, QR10, QR11, QR14, and QR16 are turned off, and common drain lines 120 and 121 are made nonconductive.

In place of N-channel MOS transistors in the second to sixth embodiments, P-channel MOS transistors may be used.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A nonvolatile semiconductor memory device comprising:
a plurality of nonvolatile memory cells;
a plurality of bit line pairs connected to said plurality of nonvolatile memory cells;
a plurality of latch circuits corresponding to said plurality of pairs of bit lines, each latching data on a corresponding bit line pair; and
a determining circuit determining whether two or more latch circuits out of said plurality of latch circuits latch predetermined data or not.

2. The nonvolatile semiconductor memory device according to claim 1,
wherein each of said latch circuits has an input node connected to one of bit lines in a corresponding bit line pair, and
said determining circuit comprises:
a plurality of transistors corresponding to said two or more latch circuits, and each having a control electrode connected to an input node of a corresponding latch circuit;
a common line connected to one conductive electrode of each of said plurality of transistors; and
a detecting circuit detecting that said common line is non-conductive.

3. The nonvolatile semiconductor memory device according to claim 1, wherein each of said latch circuits includes a sense latch having a first input node connected to one of bit lines of a corresponding bit line pair and a second input node connected to the other bit line,
said determining circuit includes a plurality of first and second transistors corresponding to two or more sense latches included in said two or more latch circuits,
the gate of each of said first transistors is connected to a first input node of a corresponding sense latch and the gate of each of said second transistors is connected to a second input node of a corresponding sense latch, and
said determining circuit further includes:
a first common drain line connected to drains of said plurality of first transistors;
a second common drain line connected to drains of said plurality of second transistors; and
a detecting circuit detecting that said first and second common drain lines are non-conductive.

4. The nonvolatile semiconductor memory device according to claim 3, wherein said detecting circuit includes:
a first detector detecting that said first common drain line is non-conductive; and
a second detector detecting that said second common drain line is non-conductive.

5. The nonvolatile semiconductor memory device according to claim 3, wherein said first and second common drain lines are connected to each other.

6. The nonvolatile semiconductor memory device according to claim 1, wherein said two or more latch circuits and said determining circuit are divided into a plurality of groups, and
each of said groups includes:
a plurality of transistors corresponding to a plurality of latch circuits in the group, each having a control electrode connected to an input node of a corresponding latch circuit;
a common line connected to one conductive electrode of each of said plurality of transistors; and
a detecting circuit detecting that said common line is non-conductive.

7. The nonvolatile semiconductor memory device according to claim 2, further comprising:
a plurality of verification transistors corresponding to latch circuits other than said two or more latch circuits out of said plurality of latch circuits, each having a control electrode connected to an input node of a corresponding latch circuit;
a verification common line connected to one conductive electrode of each of said plurality of verification transistors; and
a verification detecting circuit detecting that said verification common line is non-conductive.

8. A nonvolatile semiconductor memory device comprising:
a plurality of nonvolatile memory cells;
a plurality of bit line pairs connected to said plurality of nonvolatile memory cells;
a plurality of sense latches corresponding to said plurality of bit line pairs, each having a first input node connected to one of bit lines of a corresponding bit line pair and a second input node connected to the other bit line of the corresponding bit line pair;
a plurality of first data latches corresponding to one bit line of said plurality of bit line pairs, each having a first input node connected to a corresponding one bit line and a second input node;
a plurality of second data latches corresponding to the other bit lines of said plurality of bit line pairs, each having a first input node and a second input node connected to a corresponding other bit line;
a plurality of first and second transistors corresponding to two or more first data latches out of said plurality of first data latches;
a plurality of third and fourth transistors corresponding to two or more second data latches out of said plurality of second data latches;
the gate of each of said first transistors being connected to a first input node of a corresponding first data latch and the gate of each of said second transistors being connected to a second input node of a corresponding first data latch; and
the gate of each of said third transistors being connected to a first input node of a corresponding second data latch, and the gate of each of said fourth transistors being connected to a second input node of a corresponding second data latch;
said nonvolatile semiconductor memory device further comprising:
a first common drain line connected to the drains of said first and second transistors;
a second common drain line connected to the drains of said third and fourth transistors; and
a detecting circuit detecting that said first and second common drain lines are non-conductive.

9. A nonvolatile semiconductor memory device comprising:
a plurality of nonvolatile memory cells;
a plurality of bit line pairs connected to said plurality of nonvolatile memory cells;
a plurality of sense latches corresponding to said plurality of bit line pairs, each having a first input node connected to one of bit lines of a corresponding bit line pair and a second input node connected to the other bit line of the corresponding bit line pair;
a plurality of first data latches corresponding to one bit lines of said plurality of bit line pairs, each having an input node connected to a corresponding one bit line;
a plurality of second data latches corresponding to the other bit lines of said plurality of bit line pairs, each having an input node connected to a corresponding other bit line;
a plurality of first and second transistors corresponding to two or more sense latches out of said plurality of sense latches; and
the gate of each of said first transistors being connected to a first input node of a corresponding sense latch and the gate of each of said second transistors being connected to a second input node of a corresponding sense latch; and
said nonvolatile semiconductor memory device further comprising:
a first common drain line connected to the drains of said first transistors;
a second common drain line connected to the drains of said second transistors; and
a detecting circuit detecting that said first and second common drain lines are non-conductive.
